(19) United States
(12) Patent Application Publication
(10) Pub. No.: US 2006/0261856 A1
(43) Pub. Date: Nov. 23, 2006

(54) Semiconductor chip and semiconductor device incorporating the same

(75) Inventor: Naoki Furusawa, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/434,263

(22) Filed: May 16, 2006

(30) Foreign Application Priority Data
May 17, 2005 (JP) 2005-144648

(51) Int. Cl. H03K 19/00

(52) U.S. Cl. 326/101

(57) ABSTRACT

A semiconductor chip is composed of first and second pads receiving first and second input signals, respectively, a logic circuit, and a circuit block connected to an output of the logic circuit. The logic circuit is responsive to the first and second input signals for selecting one of the first and second input signals, and for feeding the selected one of the first and second input signals to the circuit block.

### BACKGROUND OF THE INVENTION

1. Field of the Invention

The present invention relates to semiconductor chips and semiconductor packaged devices incorporating the same. More particularly, the present invention relates to input/output pad selection of semiconductor devices.

2. Description of the Related Art

In the semiconductor device industry, different customers often require different pad arrangements for the same internal circuit design. One conventional approach for satisfying such requirement is to use differently-designed pad metal layers for different customers. However, this approach suffers from a problem that wafers manufactured for one customer are not acceptable for another customer; wafers should be dedicatedly prepared for each different customer. This is not preferable from the viewpoint of the manufacture cost.

Another approach is to electrically connect two or more input/output pads with a signal input/output signal line. However, this approach undesirably increases input capacitances of the pads.

Japanese Laid-Open patent application No. JP-A-Showa 62-244144 discloses a conventional semiconductor device for dealing with this issue, which is provided with two or more external signal pads for one internal circuit, a switch circuit for selectively connecting one of the external-signal pads to the internal circuit, and a switching control pad for receiving a signal for controlling the pad selection.

FIG. 6 is a circuit diagram of the disclosed conventional semiconductor device. The disclosed semiconductor device achieves the pad selection through bonding wires in different ways. When a switch control pad 13 is wire-bonded to a power supply terminal 14 of the power supply level Vcc, nodes N10 and N30 are pulled up to the high level, while a node N20 is pulled down to the low level. This results in that an N-channel MOS transistor 20 and a P-channel MOS transistor 50 are turned on and an N-channel MOS transistor 30 and a P-channel MOS transistor 40 are turned off. As a result, a pad 11 (for Customer “A”). is connected to an internal circuit 60, while a pad 12 (for Customer “B”) is disconnected from the internal circuit 60.

When the switch control pad 13 is not wire-bonded to the power supply terminal 14, on the other hand, an N-channel MOS transistor 10 is turned on. As a result, the nodes N10 and N30 are pulled down to the low level, while the node N20 is pulled up to the high level. This allows the N-channel MOS transistor 30 and the P-channel MOS transistor 40 to be turned on, and the N-channel MOS transistor 20 and the P-channel MOS transistor 50 to be turned off. Consequently, the pad 12 (for Customer “B”) is connected to the internal circuit 60, while the pad 11 (for Customer “A”) is disconnected from the internal circuit 60.

As explained above, the conventional semiconductor device, provided with the switch circuit and the switch control pad 13, achieves pad selection through the connection of the power supply terminal 14 with the switch control pad 13. Additionally, the conventional semiconductor device has an advantage that the input capacitance is approximately equal to that in the case of providing a single pad for the internal circuit 60, since the unused pad is disconnected from the internal circuit 60.

However, the conventional semiconductor device, which achieves pad selection through the connection of the power supply terminal 14 with the switch control pad 13, requires an additional pad for controlling the pad selection, increasing the number of pads integrated within the semiconductor device compared with the case when the pad is not duplicatedly prepared. Additionally, the arrangement of the conventional semiconductor device, which incorporate the switch circuit and the switch control pad, undesirably requires an increased chip size.

### SUMMARY OF THE INVENTION

In an aspect of the present invention, a semiconductor chip is composed of first and second pads receiving first and second input signals, respectively, a logic circuit, and a circuit block connected to an output of the logic circuit. The logic circuit is responsive to the first and second input signals for selecting one of the first and second input signals, and for feeding the selected one of the first and second input signals to the circuit block.

In one embodiment, the semiconductor chip additionally includes a first node connected between the first pad and a first input of the logic circuit, a first impedance element connected between the first node and a first terminal of a power supply, a second node connected between the second pad and a second input of the logic circuit, and a second impedance element connected between the second node and a second terminal of the power supply. The logic circuit selectively feeds the selected one of the first and second input signals, in response to the levels on the first and second input terminal thereof.

The semiconductor chip thus designed effectively improves pad selection flexibility for customers, while avoiding an undesirable increase in the input capacitance and the chip size.

The levels of the first and second terminals of the power supply may be fixed to the ground level (or the low level). In this case, the first logic circuit is composed of an OR circuit. In the semiconductor chip thus constructed, the non-bonded one of the first and second pads is pulled down to the ground level. Therefore, the OR circuit transfers the selected one of the first and second input signals, which is inputted to the bonded one of the first and second pads.

Alternatively, the levels of the first and second terminals of the power supply may be fixed to the power supply level (or the high level). In this case, the first logic circuit is composed of an AND circuit. In the semiconductor chip thus constructed, the non-bonded one of the first and second pads is pulled up to the power supply level. Therefore, the AND circuit transfers the selected one of the first and second input signals, which is inputted to the bonded one of the first and second pads.

The semiconductor chip may be additionally includes a second logic circuit connected between said first logic circuit and said circuit block. The second logic circuit is configured to receive the selected one of the first and second input signals and a synchronization signal, and to feed the circuit block with a third input signal generated from the selected one of the first and second input signals and the synchronization signal.

In another aspect of the present invention, a semiconductor device is composed of an external terminal, and the above-described semiconductor chip. One of the first and second pads is electrically connected to the external terminal. The first logic circuit selects one of the first and second input signals, the one being associated with the electrically connected one of the first and second pads. The semiconductor device thus constructed automatically achieves pad selection through electrically connecting desired one of the first and second pads.

### BRIEF DESCRIPTION OF THE DRAWINGS

The above and other advantages and features of the present invention will be more apparent from the following description taken in conjunction with the accompanied drawings, in which:

FIG. 1 is a block diagram illustrating a structure of a semiconductor chip in a first embodiment of the present invention;

FIG. 2 is a block diagram illustrating a structure of a semiconductor chip in a second embodiment of the present invention;

FIG. 3 is a block diagram illustrating a structure of a semiconductor chip in a third embodiment of the present invention;

FIG. 4A illustrates a structure of a semiconductor device designed for Customer “A”, in which one of the pads is wire-bonded to an external terminal;

FIG. 4B illustrates a structure of a semiconductor device designed for Customer “B”, in which another of the pads is wire-bonded to an external terminal;

FIG. 5A illustrates a structure of a semiconductor device for Customer “A”, in which one of the pads is electrically connected to an external terminal through a solder ball;

FIG. 5B illustrates a structure of a semiconductor device for Customer “B”, in which another of the pads is electrically connected to an external terminal through a solder ball; and

FIG. 6 is a block diagram illustrating a structure of a conventional semiconductor chip.

### DESCRIPTION OF THE PREFERRED EMBODIMENTS

The invention will be now described herein with reference to illustrative embodiments. Those skilled in the art would recognize that many alternative embodiments can be accomplished using the teachings of the present invention and that the invention is not limited to the embodiments illustrated for explanatory purposed.

In the following embodiments, descriptions are given with an example of a semiconductor chip 100 incorporating two signal input pads used for satisfying pad arrangement requirements of Customers “A” and “B”, respectively.

### First Embodiment

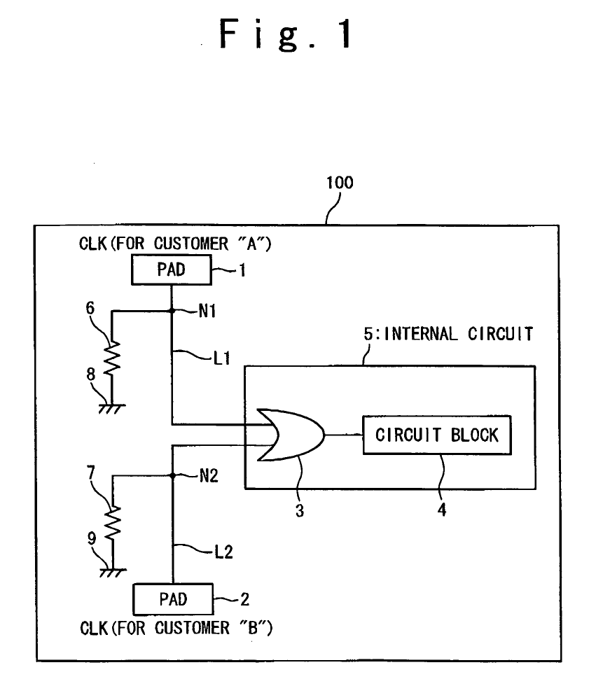

FIG. 1 is a block diagram illustrating an exemplary structure of a semiconductor chip 100 in a first embodiment of the present invention.

The semiconductor chip 100 of the present invention is provided with a pad 1 for Customer “A”, a pad 2 for Customer “B”, and an internal circuit 5. The internal circuit 5 includes an OR circuit 3 and a circuit block 4. The OR circuit 3 is connected to the pad 1 through a node N1 on an interconnection line L1, and also connected to pad 2 through a node N2 on an interconnection line L2. Impedance elements having sufficient resistances to satisfy an input leakage standard are connected to the nodes N1 and N2, respectively. In this embodiment, a pull-down resistor 6 is connected between the node N1 and a ground terminal 8 (a terminal of the ground level or the low level). Correspondingly, another pull-down resistor 7 is connected between the node N2 and a ground terminal 9.

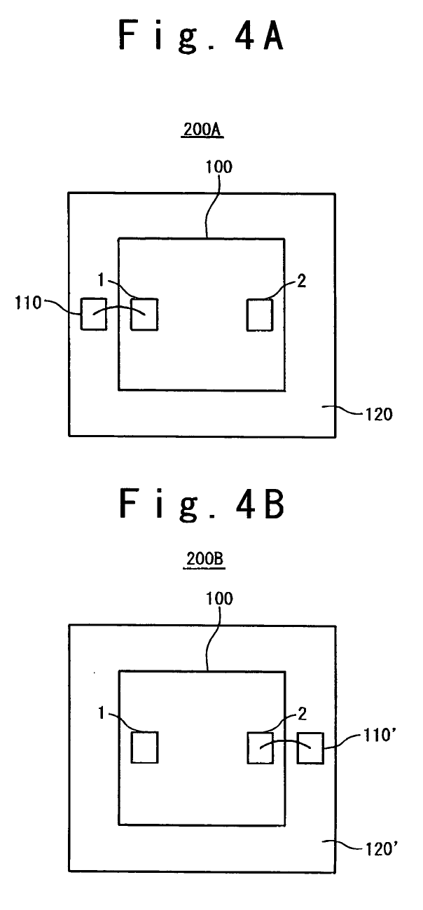

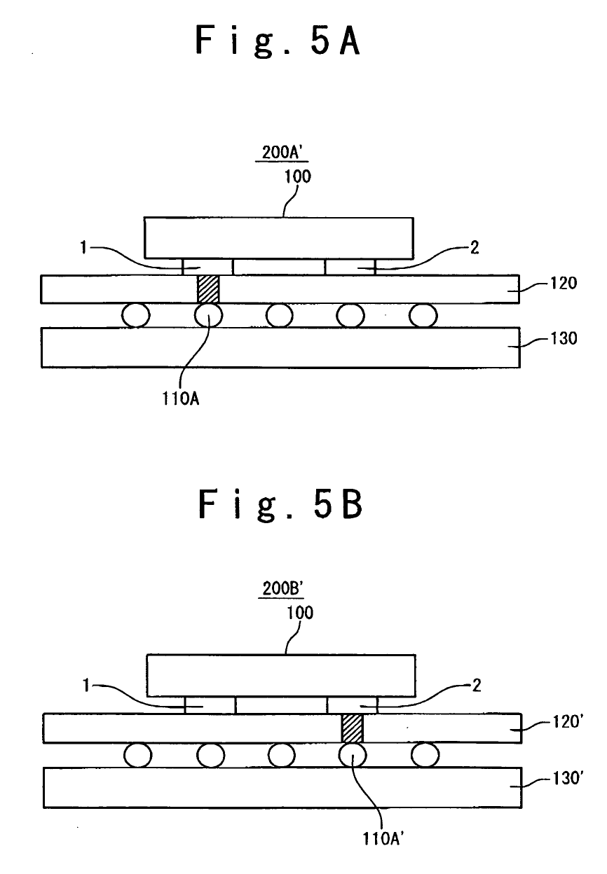

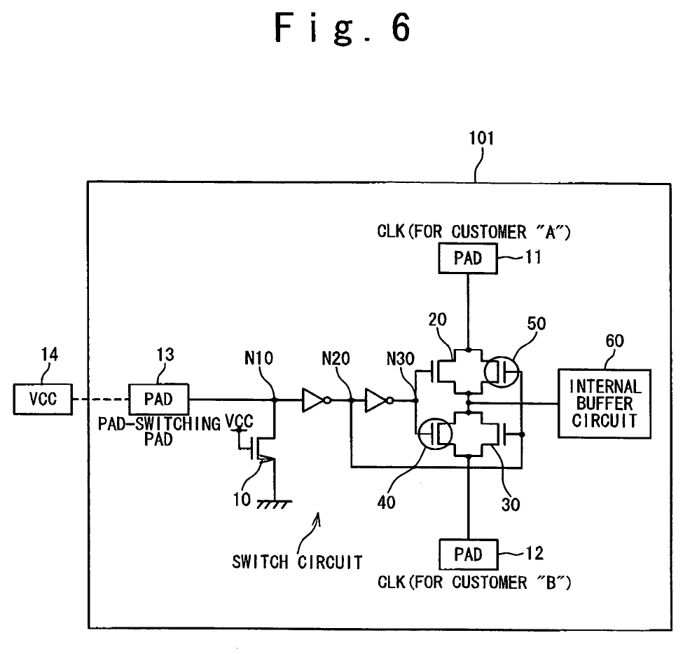

FIG. 4A illustrates an exemplary structure of a semiconductor device 200A in which the semiconductor chip 100 is packaged so as to satisfy the requirement of Customer “A”. The semiconductor device 200A includes an external terminal 110 provided on a substrate 120. The pad 1, which is prepared for Customer “A”, is wire-bonded to the external terminal 110 with the pad 2 non-bonded.

Alternatively, the semiconductor chip 100 may be packaged within a semiconductor device 200A′ in which the pad 1 is electrically connected to a solder ball 110A by a via-contact provided through a substrate 120. The solder ball 110A functions as an external terminal to be connected with a pad provided on a printed circuit board 130.

In the semiconductor device 200A (or 200A′), the pad 1 for Customer “A” is electrically connected to the external terminal, while the pad 2 for Customer “B” is isolated from the external terminal. As a result, a signal level of the node N2 is fixed to the low level by the pull-down resistor 7, which is connected to the pad 2. The OR circuit 3 receives an input signal from the external terminal 110 through the pad 1 and a signal of the low level from the interconnection line L2. This results in that the OR circuit 3 transfers the input signal received from the pad 1 to the circuit block 4 of the internal circuit 5.

It should be noted that the input capacitance of the pad 1 is approximately equal to the input capacitance in the case when a single pad is connected to the circuit block 4 in place of the pads 1 and 2 and the OR circuit 3, since the OR circuit 3 is connected to the pads 1 and 2 through the separate interconnection lines L1 and L2.

In order to satisfy the requirement of Customer “B”, on the other hand, the semiconductor chip 100 is incorporated within a semiconductor device 200B in which the pad 2, which is prepared for Customer “B”, is wire-bonded to the external terminal 110 with the pad 1 non-bonded.

Alternatively, the semiconductor chip 100 may be packaged within a semiconductor device 200B′ in which the pad 2 is electrically connected to a solder ball 110A by a via-contact provided through a substrate 120. The solder ball 110A functions as an external terminal to be connected with a pad provided on a printed circuit board 130.

In the semiconductor device 200B (or 200B′), the pad 2 for Customer “B” is electrically connected to the external terminal, while the pad 1 for Customer “A” is isolated from the external terminal. As a result, a signal level of the node N1 is fixed to the low level by the pull-down resistor 6, which is connected to the pad 1. This results in that the OR circuit 3 transfers the input signal received from the pad 2 to the circuit block 4. Additionally, the input capacitance of the pad 2 is approximately equal to the input capacitance in the case when a single pad is connected to the circuit block 4 in place of the pads 1 and 2 and the OR circuit 3.

In summary, the semiconductor device in this embodiment, in which the interconnection line connected to the electrically isolated pad is fixed to the low level and the OR circuit 3 generates the logical OR of the signal level of externally-received input signal and the signal level of the electrically isolated pad, achieves selecting desired one of the pads 1 and 2 through electrically connecting only the desired one to the external terminal.

Additionally, the semiconductor device in this embodiment eliminates the need for providing a switch circuit for selecting pads and a switch control pad for controlling the switch circuit. This effectively reduces the chip size.

Furthermore, the semiconductor device effectively avoids the increase in the input capacitance of a pad connected to an external terminal over the input capacitance in the case when the semiconductor chip 100 incorporates a single pad instead of the pads 1 and 2 and the OR circuit 3, since the OR circuit 3 is connected to the pads 1 and 2 through separate interconnection lines.

### Second Embodiment

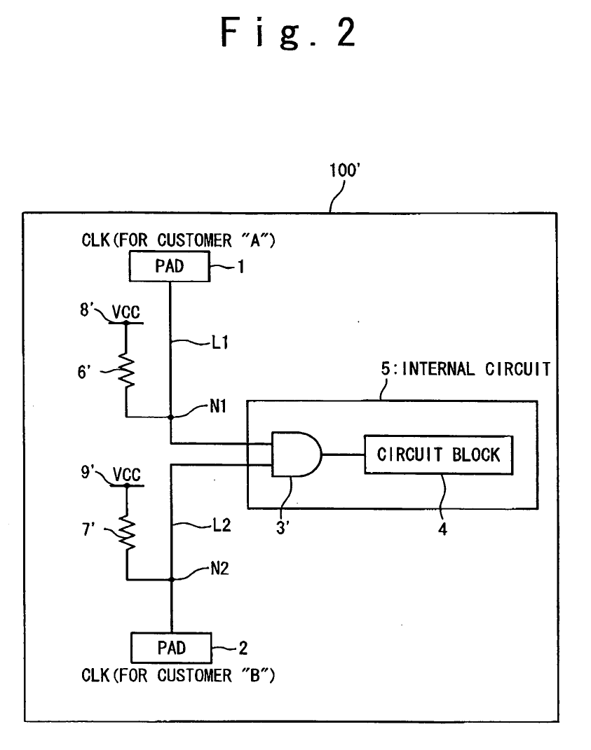

FIG. 2 is a block diagram illustrating an exemplary structure of a semiconductor chip 100′ in a second embodiment of the present invention. The semiconductor chip 100′ in the second embodiment is almost similar to the semiconductor chip 100 in the first embodiment. The difference is as follows:

The semiconductor chip 100′ is provided with an AND circuit 3′ instead of the OR circuit 3 in the first embodiment. Additionally, the pull-down resistor 6 is replaced with a pull-up resistor 6′ connected between the node N1 and a power supply terminal 8′ of the power supply level VCC (or the high level). Correspondingly, the pull-down resistor 7 is replaced with a pull-up resistor 7′ between the node N2 and a power supply terminal 9′.

The semiconductor chip 100′ in the second embodiment operates in the same way as the semiconductor chip 100 in the first embodiment.

In order to satisfy the requirement of Customer “A”, the pad 1 is wire-bonded to the external terminal 110, while the pad 2 is not wire-bonded. This allows the signal level of the node N2 connected to the non-bonded pad 2 is fixed to the high level by the pull-up resistor 7′. The AND circuit 3′ receives an input signal from the external terminal 110 through the pad 1, and a signal of the high level from the interconnection line L2. This allows the AND circuit 3′ to transfer the input signal received from the pad 1 to the circuit block 4 of the internal circuit 5. It should be noted that the input capacitance of the pad 1 is approximately be equal to the input capacitance in the case when a single pad is connected to the circuit block 4 in place of the pads 1 and 2 and the AND circuit 3′, since the AND circuit 3′ is connected to the pads 1 and 2 through the separate interconnection lines L1 and L2.

In order to satisfy the requirement of Customer “B”, on the other hand, the pad 2 is wire-bonded to the external terminal 110, while the pad 1 is not wire-bonded. This allows the signal level of the node N1 connected to the non-bonded pad 1 is fixed to the high level by the pull-up resistor 6′. As a result the AND circuit 3′ transfers the input signal received from the pad 2 to the circuit block 4 of the internal circuit 5. It should be noted that the input capacitance of the pad 2 is approximately be equal to the input capacitance in the case when a single pad is connected to the circuit block 4 in place of the pads 1 and 2 and the AND circuit 3′.

In summary, the semiconductor device in this embodiment, in which the interconnection line connected to the electrically isolated pad is fixed to the high level and the AND circuit 3′ generates the logical AND of the signal level of externally-received input signal and the signal level of the electrically isolated pad, achieves selecting desired one of the pads 1 and 2 through electrically connecting only the desired one to the external terminal.

Additionally, the semiconductor device in this embodiment eliminates the need for providing a switch circuit for selecting pads and a switch control pad for controlling the switch circuit. This effectively reduces the chip size.

Furthermore, the semiconductor device in this embodiment effectively avoids the increase in the input capacitance of a pad connected to an external terminal over the input capacitance in the case when the semiconductor chip 100′ incorporates a single pad instead of the pads 1 and 2 and the OR circuit 3, since the AND circuit 3′ is connected to the pads 1 and 2 through separate interconnection lines.

### Third Embodiment

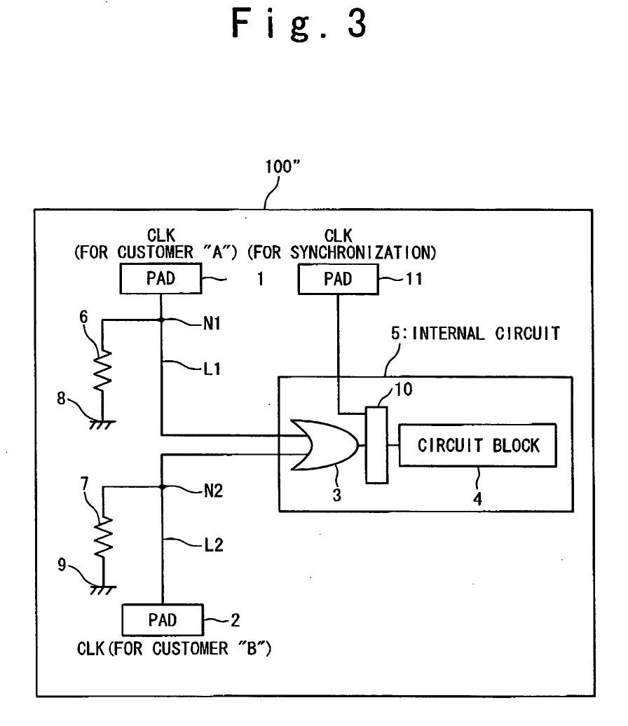

FIG. 3 is a block diagram illustrated an exemplary structure of a semiconductor chip 100″ in a third embodiment of the present invention.

The semiconductor chip 100″ is directed to synchronization of an input signal received from an external terminal with a synchronization signal. With reference to FIG. 3, a synchronization circuit 10, which is composed of logic circuits, such as OR gates and AND gates, is provided between the OR circuit 3 and the circuit block 4. An input of synchronization circuit 10 is connected with a pad 11 receiving an externally-provided synchronization signal.

The synchronization circuit 10 achieves synchronization of the input signal received from the selected pad with the synchronization signal, and feeds the circuit block 4 with the input signal synchronized with the synchronization signal. In an alternative embodiment, the synchronization circuit 10 may be provided between the AND circuit 3′ and the circuit block 4 in the second embodiment, having an input connected with the pad 11 receiving the externally-provided synchronous signal.

In summary, the semiconductor chip of the present invention selects pads by inputting an input signal to be fed to the internal circuit to the desired pad, not by feeding a control signal for selecting the pads. This eliminates the need for providing a switch circuit that selects pads and a switch control pad for controlling the switch circuit. This effectively reduces the chip size.

It should be noted that the semiconductor chip of the present invention, which does not incorporate a switch circuit connected to pads, is applicable to output pads.

As explained above, the semiconductor chip according to the present invention effectively improves pad selection flexibility for customers, while avoiding an undesirable increase in the input capacitance and the chip size.

It is apparent that the present invention is not limited to the above-described embodiments, which may be modified and changed without departing from the scope of the invention.

What is claimed is:

1. A semiconductor chip comprising:
first and second pads for receiving first and second input signals, respectively;
a logic circuit; and
a circuit block connected to an output of said logic circuit,
wherein said logic circuit is responsive to said first and second input signals for selecting one of said first and second input signals, and feeding said selected one of said first and second input signals to said circuit block.

2. The semiconductor chip according to claim 1, further comprising:
a first node connected between said first pad and a first input of said logic circuit;
a first impedance element connected between said first node and a first terminal of a power supply;
a second node connected between said second pad and a second input of said logic circuit; and
a second impedance element connected between said second node and a second terminal of said power supply,
wherein said logic circuit selectively feeds said selected one of said first and second input signals, in response to levels on said first and second input terminal thereof.

3. The semiconductor chip according to claim 2, wherein levels of said first and second terminals of said power supply are fixed to a ground level, and
wherein said first logic circuit includes an OR circuit.

4. The semiconductor chip according to claim 2, wherein levels of said first and second terminals of said power supply are fixed to a power supply level, and
wherein said first logic circuit includes an AND circuit.

5. The semiconductor chip according to claim 2, further comprising a second logic circuit connected between said first logic circuit and said circuit block,
wherein said second logic circuit is configured to receive said selected one of the first and second input signals and a synchronization signal, and to feed the circuit block with a third input signal generated from said selected one of said first and second input signals and said synchronization signal.

6. A semiconductor device comprising:
a semiconductor chip; and
an external terminal,
wherein said semiconductor chip includes;
first and second pads for receiving first and second input signals, respectively;
a logic circuit; and
a circuit block connected to an output of said logic circuit,
wherein said logic circuit is responsive to said first and second input signals for selecting one of said first and second input signals,
wherein one of said first and second pads is connected to said external terminal; and
wherein said external terminal is used to feed said selected one of said first and second input signals to said one of said first and second pads.
